(19) United States
(12) Patent Application Publication
(10) Pub. No.: US 2009/0075473 A1
(43) Pub. Date: Mar. 19, 2009

(54) METHOD FOR FABRICATING SEMICONDUCTOR DEVICE

(76) Inventor: Jung-Bae Kim, Ansan-si (KR)

Correspondence Address: SHERR & VAUGHN, PLLC, 620 HERNDON PARKWAY, SUITE 200, HERNDON, VA, 20170, US

(21) Appl. No.: 12/131,203

(22) Filed: Jun. 2, 2008

(30) Foreign Application Priority Data
Sep. 17, 2007 (KR) 10-2007-0094313

(51) Int. Cl. H01L 21/4763

(52) U.S. Cl. 438/637; 257/E21.495

(57) ABSTRACT

A method for fabricating a semiconductor device capable of improving electrical junction capability between a pad metal line and an upper metal line by removing a foreign substance present on the surface of the pad metal line prior to formation of the upper metal line.

The present application claims priority under 35 U.S.C. 119 to Korean Patent Application No. 10-2007-0094313 (filed on Sep. 17, 2007), which is hereby incorporated by reference in its entirety.

### BACKGROUND

Wafer level package (WLP) semiconductor processes may employ generally methods for forming upper metal lines through depositing pad metal lines, and etching the deposited pad metal, without any additional processes. In during WLP processing a high probability exists of the generation of foreign substances at the interface between a pad metal line and an upper metal line, due to a large contact area between these metal lines. When semiconductor processes are performed under the condition that the foreign substance is present on the interface, problems occur in that the lines may become seriously damaged, and thus, cannot perform their electrical functions.

### SUMMARY

Embodiments relate to a method for fabricating a semiconductor device that can enhance electrical junction capability between a pad metal line and an upper metal line.

Embodiments relate to a method for fabricating a semiconductor device that enhances electrical junction capability between a pad metal line and an upper metal line by removing foreign substances present on the interface between the lines through sputtering or using an excimer laser.

Embodiments relate to a method for fabricating a semiconductor device that can include at least one of the following steps: providing a substrate having a plurality of transistors; and then forming a plurality of metal lines on and/or over the substrate; and then forming an insulating layer on and/or over the entire surface of the substrate including the metal lines; and then selectively removing a portion of the insulating layer arranged in a pad region exposing a pad metal line arranged in the pad region among the metal lines; and then removing foreign substances present on and/or over the surface of the pad metal line; and then forming an upper metal line on and/or over the insulating layer thereby connecting the upper metal line to the pad metal line.

Embodiments relate to a method for fabricating a semiconductor device that can include at least one of the following steps: forming a plurality of first metal lines on a substrate having a plurality of transistors; and then forming a first insulating layer on the substrate including the first metal lines; and then forming a plurality of first contact plugs on the first metal lines; and then forming a plurality of second metal lines on the substrate including the first insulating layer and the first contact plugs; and then forming a plurality of second contact plugs on the second metal lines; and then forming a pad metal line in a pad region of the substrate and on the second insulating layer including the second contact plugs; and then forming a third insulating layer on the substrate including the pad metal line; and then forming a foreign substance on the surface of the pad metal line; and then removing the foreign substance from the surface of the pad metal line; and then forming an upper metal line electrically connected to the pad metal line.

Embodiments relate to a method for fabricating a semiconductor device that can include at least one of the following steps: forming a plurality of metal lines on a substrate having a plurality of transistors; and then forming a plurality of first contact plugs on the substrate including the first metal lines; and then forming a plurality of second metal lines on the substrate including the first contact plugs; and then forming a plurality of second contact plugs on the substrate including the second metal lines; and then forming a pad metal line in a pad region of the substrate and on at least some of the second contact plugs; and then forming a AlO₃ on the surface of the pad metal line; and then removing the AlO₃ layer from the surface of the pad metal line by exposing the AlO₃ layer to at least one of argon gas and an excimer laser; and then forming an upper metal line electrically connected to the pad metal line.

### DRAWINGS

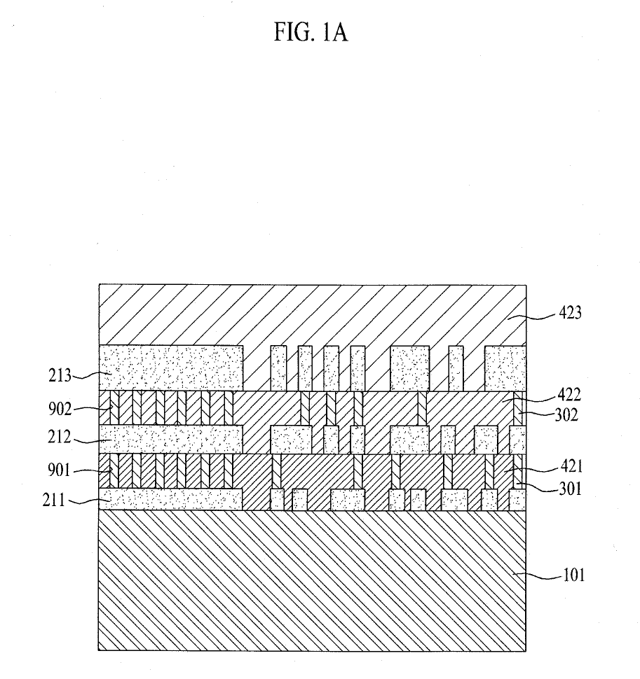

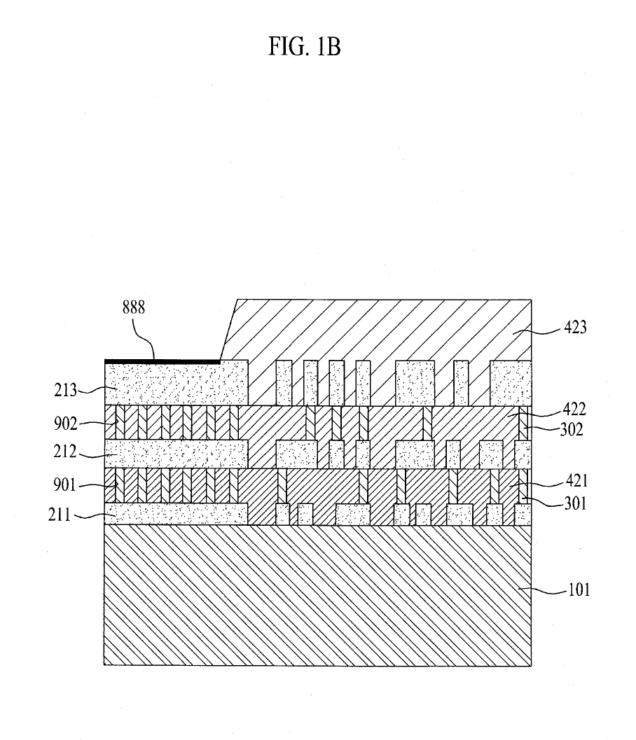

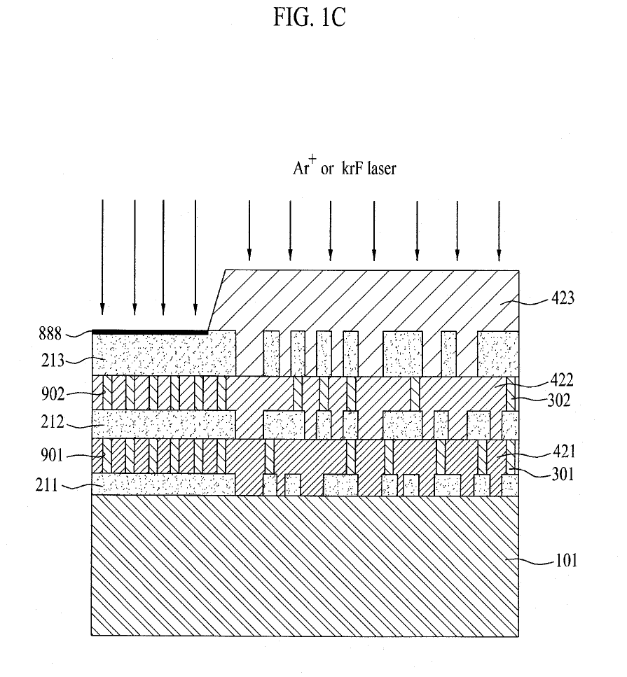

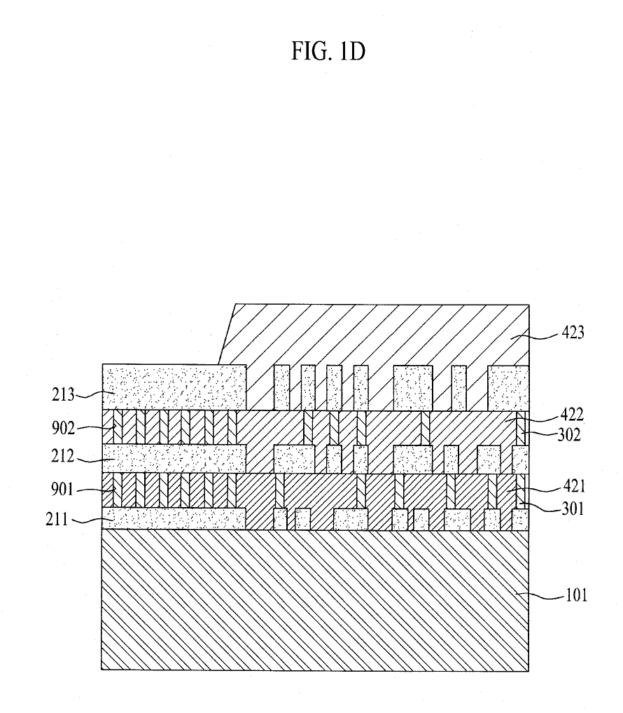

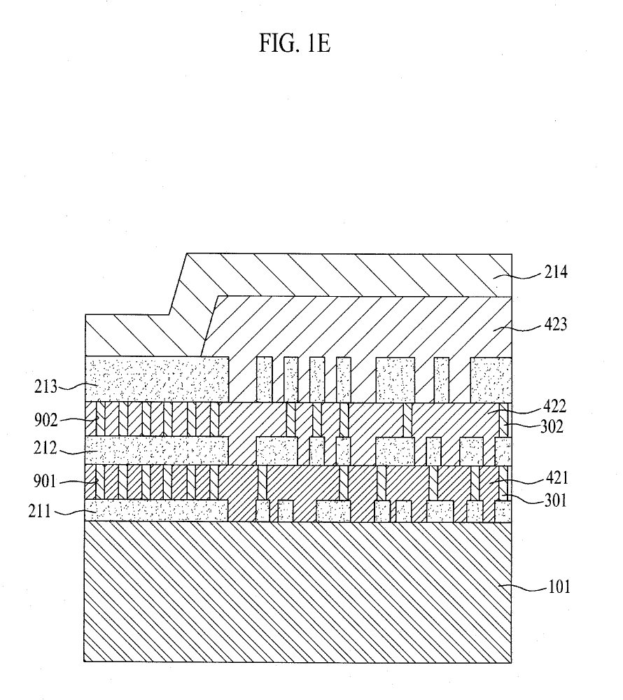

Example FIGS. 1A to 2E illustrate a method for fabricating a semiconductor device, in accordance with embodiments.

### DESCRIPTION

As illustrated in example FIG. 1A, substrate 101 provided with a plurality of transistors can be prepared and a first metal layer can then be deposited on and/or over the entire surface of substrate 101. The first metal layer can then be patterned through photolithographic and etching processes to form a plurality of first metal lines 211. Subsequently, first insulating layer 421 can be formed on and/or over the entire surface of substrate 101 including first metal lines 211. First insulating layer 421 can then be partially etched to form a plurality of first via holes 901 through which first metal lines 211 are exposed. A material composed of a metal such as tungsten can then be deposited on and/or over the entire surface of substrate 101 including first via holes 901. The tungsten layer can then be planarized by chemical mechanical polishing (CMP) to form first contact plugs 301 inside via holes 901.

A second metal layer can then be deposited on and/or over the entire surface of substrate 101 including first insulating layer 421 and first contact plugs 301. The second metal layer can then be patterned through photolithographic and etching processes to form a plurality of second metal lines 212. Second insulating layer 422 can then be formed on and/or over the entire surface of substrate 101 including second metal lines 212. Second insulating layer 422 can then be partially etched to form a plurality of second via holes 902 through which second metal lines 212 are exposed. A material composed of a metal such as tungsten can then be deposited on and/or over the entire surface of substrate 101 including second via holes 902. The tungsten layer can then be planarized by chemical mechanical polishing (CMP) to form second contact plugs 302 inside via holes 902.

A third metal layer can then be deposited on and/or over the entire surface of substrate 101 including second insulating layer 422 and second contact plugs 302. The third metal layer can then be patterned through photolithographic and etching processes to form a plurality of third metal lines. Third insulating layer 423 can then be formed on and/or over the entire surface of substrate 101 including the third metal lines. Third insulating layer 423 may be an oxide film.

As illustrated in example FIG. 1B, third insulating layer 423 can then be partially patterned thorough photolithographic and etching processes to expose pad metal line 213 located in a pad region among the third metal lines. During photolithographic and etching processes, oxides produced from third insulating layer 423 and pad metal line 213, respectively, chemically react with each other to produce by-products. These by-products are formed on and/or over the surface of pad metal line 213. More specifically, O₃ produced from third insulating layer 423 and Al produced from pad metal line 213 chemically react with each other to form foreign substance 888, namely the by-product AlO₃. Foreign substance 888 is formed on and/or over the surface of pad metal line 213, thus causing deterioration of electrical junction capability between pad metal line 213 and upper metal line 214. Accordingly, in accordance with embodiments, prior to formation of upper metal line 214, foreign substance 888 is removed from the surface of pad metal line 213, thereby improving the electrical junction capability between pad metal line 213 and upper metal line 214.

As illustrated in example FIG. 1C, to achieve such improvement, a sputtering process can be performed under the condition that pad metal line 213 is exposed to the outside, to thereby remove foreign substance 888 from the surface of pad metal line 213. The sputtering process can be performed using an argon (Ar+) gas. Alternatively, an excimer laser can be used instead of the sputtering process to remove foreign substance 888 formed on and/or over pad metal line 213. Meaning, the surface of pad metal line 213 can be selectively subjected to excimer laser irradiation using energy of about 250 mW/cm² for several milliseconds to thereby remove foreign substance 888 from the surface of pad metal line 213. In accordance with embodiments, the excimer laser irradiation can be performed using a KrF excimer laser, which has a dissociation energy that is greater than that of foreign substance 888, i.e. AlO₃. For this reason, when the KrF excimer laser is irradiated to the AlO₃, the bond between the Al and O₃ is readily broken and the O₃ is then removed.

As illustrated in example FIG. 1D, when the AlO₃ is removed by performing a sputtering process or by using an excimer laser, the surface of pad metal line 213 is exposed. A fourth deposition metal layer can then be deposited on and/or over the entire surface of substrate 101 including pad metal line 213. The fourth metal layer can then be patterned through photolithographic and etching processes. As a result, as illustrated in example FIG. 1E, upper metal line 214 can be formed electrically connected to pad metal line 213 and arranged on and/or over third insulating layer 423.

As apparent from the foregoing, in accordance with the method of the present invention, prior to formation of the upper metal line, the foreign substance present on the surface of the pad metal line is removed, thereby improving the electrical junction capability between the pad metal line and the upper metal line.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a semiconductor device comprising:
forming a plurality of metal lines on a substrate; and then
forming an insulating layer on the substrate including the metal lines; and then
selectively removing a portion of the insulating layer arranged in a pad region to expose a pad metal line in the pad region; and then
removing a foreign substance from the surface of the pad metal line; and then
forming an upper metal line on the insulating layer electrically connected to the pad metal line.

2. The method of claim 1, wherein removing the foreign substance comprises removing the foreign substance using a sputtering process.

3. The method of claim 2, wherein the sputtering process is performed using argon gas.

4. The method of claim 1, wherein removing the foreign substance comprises irradiating a laser to the surface of the pad metal line.

5. The method of claim 4, wherein the laser comprises an excimer laser.

6. The method of claim 5, wherein the excimer laser is irradiated to the surface of the pad metal line at an energy level of 250 mW/cm².

7. A method of fabricating a semiconductor device comprising:
forming a plurality of first metal lines on a substrate; and then
forming a first insulating layer on the substrate including the first metal lines; and then
forming a plurality of first contact plugs on the first metal lines; and then
forming a plurality of second metal lines on the substrate including the first insulating layer and the first contact plugs; and then
forming a plurality of second contact plugs on the second metal lines; and then
forming a plurality of third metal lines including a pad metal line in a pad region of the substrate and on the second insulating layer including the second contact plugs; and then
forming a third insulating layer on the substrate including the pad metal line; and then
forming a foreign substance on the surface of the pad metal line; and then
removing the foreign substance from the surface of the pad metal line; and then
forming an upper metal line electrically connected to the pad metal line.

8. The method of claim 7, wherein the first contact plugs and the second contact plugs comprise a metal layer

9. The method of claim 8, wherein the metal layer comprises tungsten.

10. The method of claim 7, wherein the third insulating layer comprises an oxide material.

11. The method of claim 7, wherein forming the foreign substance comprises partially patterning the third insulating layer to expose the pad metal line.

12. The method of claim 11, wherein partially patterning the third insulating layer comprises partially patterning the third insulating layer through photolithographic and etching processes.

13. The method of claim 12, wherein the foreign substance comprises AlO₃.

14. The method of claim 7, wherein the foreign substance comprises AlO₃.

15. The method of claim 7, wherein removing the foreign substance comprises performing a sputtering process on the surface of the pad metal line.

16. The method of claim 15, wherein the sputtering process is performed using argon gas.

17. The method of claim 7, wherein removing the foreign substance comprises irradiating laser light to the surface of the pad metal line.

18. The method of claim 17, wherein the laser light is irradiated using an excimer laser.

19. The method of claim 18, wherein the excimer laser irradiates laser light to the surface of the pad metal line at an energy level of 250 mW/cm².

20. A method of fabricating a semiconductor device comprising:
forming a plurality of metal lines on a substrate; and then
forming a plurality of first contact plugs on the substrate including the first metal lines; and then
forming a plurality of second metal lines on the substrate including the first contact plugs; and then
forming a plurality of second contact plugs on the substrate including the second metal lines; and then
forming a pad metal line in a pad region of the substrate and on at least some of the second contact plugs; and then
forming a AlO₃ on the surface of the pad metal line; and then
removing the AlO₃ layer from the surface of the pad metal line by exposing the AlO₃ layer to at least one of argon gas and an excimer laser; and then
forming an upper metal line electrically connected to the pad metal line.
